(19) United States
(12) Patent Application Publication
(10) Pub. No.: US 2025/0366277 A1
(43) Pub. Date: Nov. 27, 2025

(54) LIGHT-EMITTING DEVICE

(71) Applicant: Nichia Corporation, Anan-shi (JP)

(72) Inventor: Hiroki KONDO, Anan-shi (JP)

(73) Assignee: Nichia Corporation, Anan-shi (JP)

(21) Appl. No.: 19/211,810

(22) Filed: May 19, 2025

(30) Foreign Application Priority Data
May 23, 2024 (JP) 2024-083965
Dec. 2, 2024 (JP) 2024-209746

(51) Int. Cl. H10H 20/855

(52) U.S. Cl. CPC H10H 20/855

(57) ABSTRACT

A light-emitting device includes: a semiconductor part including a light-emitting layer; a dielectric film disposed on an upper surface of the semiconductor part and including an oxide; and a light-transmissive member disposed on an upper surface of the dielectric film. A refractive index of the dielectric film is lower than a refractive index of the semiconductor part and is closer to a refractive index of a light-transmissive member than to the refractive index of the semiconductor part. The oxide contains Al and Ta. When a sum of an Al content in the oxide and a Ta content in the oxide is taken as 100 atomic %, the Ta content is greater than 0 atomic % and less than or equal to 60 atomic %.

### CROSS-REFERENCE TO RELATED APPLICATIONS

This application is based on and claims priority to Japanese Patent Application No. 2024-083965, filed on May 23, 2024, and Japanese Patent Application No. 2024-209746, filed on Dec. 2, 2024, the entire contents of which are incorporated herein by reference.

### TECHNICAL FIELD

The present disclosure relates to a light-emitting device.

### BACKGROUND

Japanese Patent Publication No. 2017-174909 describes a light-emitting device including light-emitting parts formed on a surface of a transparent substrate. In some light-emitting devices, a dielectric film is disposed between a transparent substrate and light-emitting parts.

### SUMMARY

An object of an embodiment of the present disclosure is to provide a light-emitting device that can improve light extraction efficiency while improving the bonding strength between a dielectric film and a light-transmissive member.

According to one aspect of the disclosed technology, a light-emitting device includes: a semiconductor part including a light-emitting layer; a dielectric film disposed on an upper surface of the semiconductor part and including an oxide; and a light-transmissive member disposed on an upper surface of the dielectric film. A refractive index of the dielectric film is lower than a refractive index of the semiconductor part and is closer to a refractive index of a light-transmissive member than to the refractive index of the semiconductor part. The oxide contains Al and Ta. When a sum of an Al content in the oxide and a Ta content in the oxide is taken as 100 atomic %, the Ta content is greater than 0 atomic % and less than or equal to 60 atomic %.

According to one aspect of the disclosed technology, a light-emitting device includes: a semiconductor part including a light-emitting layer; a first light-transmissive member disposed on an upper surface of the semiconductor part; a dielectric film disposed on an upper surface of the first light-transmissive member and including an oxide; a second light-transmissive member disposed on an upper surface of the dielectric film. A refractive index of the dielectric film is lower than a refractive index of the semiconductor part and is closer to a refractive index of the second light-transmissive member than to the refractive index of the semiconductor part. A refractive index of the first light-transmissive member is lower than the refractive index of the semiconductor part and is closer to the refractive index of the dielectric film than to the refractive index of the semiconductor part. The oxide contains Al and Ta. When a sum of an Al content in the oxide and a Ta content in the oxide is taken as 100 atomic %, the Ta content is greater than 0 atomic % and less than or equal to 60 atomic %.

### BRIEF DESCRIPTION OF THE DRAWINGS

FIG. 1 is a cross-sectional view illustrating a light-emitting device according to a first embodiment;

FIG. 2 is a diagram illustrating the relationship among the composition, the surface energy, and the refractive index of each dielectric film;

FIG. 3 is a diagram illustrating the relationship between the composition and the light transmittance of each dielectric film;

FIG. 4 is a diagram illustrating the relationship between the composition and the light transmittance of each dielectric film;

FIG. 5 is a diagram illustrating the relationship between the content of Ta in an oxide and light extraction efficiency;

FIG. 6 is a cross-sectional view illustrating a method of manufacturing the light-emitting device according to the first embodiment;

FIG. 7 is a cross-sectional view illustrating the method of manufacturing the light-emitting device according to the first embodiment;

FIG. 8 is a cross-sectional view illustrating the method of manufacturing the light-emitting device according to the first embodiment;

FIG. 9 is a cross-sectional view illustrating the method of manufacturing the light-emitting device according to the first embodiment;

FIG. 10 is a cross-sectional view illustrating the method of manufacturing the light-emitting device according to the first embodiment;

FIG. 11 is a cross-sectional view illustrating the method of manufacturing the light-emitting device according to the first embodiment;

FIG. 12 is a cross-sectional view illustrating the method of manufacturing the light-emitting device according to the first embodiment;

FIG. 13 is a cross-sectional view illustrating the method of manufacturing the light-emitting device according to the first embodiment;

FIG. 14 is a plan view illustrating the method of manufacturing the light-emitting device according to the first embodiment;

FIG. 15 is a cross-sectional view illustrating a light-emitting device according to a second embodiment;

FIG. 16 is a cross-sectional view illustrating a method of manufacturing the light-emitting device according to the second embodiment;

FIG. 17 is a cross-sectional view illustrating the method of manufacturing the light-emitting device according to the second embodiment;

FIG. 18 is a cross-sectional view illustrating the method of manufacturing the light-emitting device according to the second embodiment;

FIG. 19 is a cross-sectional view illustrating the method of manufacturing the light-emitting device according to the second embodiment;

FIG. 20 is a cross-sectional view illustrating the method of manufacturing the light-emitting device according to the second embodiment; and

FIG. 21 is a cross-sectional view illustrating the method of manufacturing the light-emitting device according to the second embodiment.

### DETAILED DESCRIPTION

Embodiments of the present disclosure will be described below with reference to the accompanying drawings. The following description is provided for the purpose of embodying the technical ideas of the present disclosure, but the present disclosure is not limited to the embodiments in the following description unless specifically stated.

In the drawings, members having the same functions may be denoted by the same reference numerals. In consideration of ease of explanation or ease of understanding of key points, configurations may be illustrated in separate embodiments for the sake of convenience; however, such configurations illustrated in different embodiments or examples can be partially substituted or combined with one another. A description of an embodiment given after a description of another embodiment will be focused mainly on matters different from those of the previously described embodiment, and a duplicate description of matters common to the previously described embodiment may be omitted. The sizes, positional relationships, and the like of members illustrated in the drawings may be exaggerated for a better understanding of the structures. Further, to avoid excessive complication of the drawings, a view in which some elements are not illustrated may be used, or an end view illustrating only a cut surface may be used as a cross-sectional view.

### First Embodiment

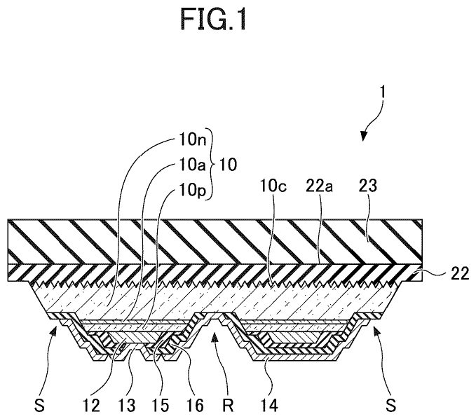

A first embodiment relates to a light-emitting device. FIG. 1 is a cross-sectional view illustrating the light-emitting device according to the first embodiment.

A light-emitting device 1 according to the first embodiment includes a semiconductor part 10, a dielectric film 22, and a light-transmissive member 23. In the following description, a length in a direction orthogonal to an upper surface 10c of the semiconductor part 10 and toward the dielectric film 22 may be referred to as a height or a thickness.

The semiconductor part 10 includes a first semiconductor layer 10n, a light-emitting layer 10a, and a second semiconductor layer 10p, which are layered in this order. The light-emitting layer 10a is located between the first semiconductor layer 10n and the second semiconductor layer 10p. In the present embodiment, the first semiconductor layer 10n includes an n-type semiconductor, and the second semiconductor layer 10p includes a p-type semiconductor. The light-emitting layer 10a includes a plurality of barrier layers and a plurality of well layers, and can have a multi-quantum well structure in which the barrier layers and the well layers are alternately layered. For example, the semiconductor part 10 has a rectangular shape in a plan view. In a case where the semiconductor part 10 has a rectangular shape in a plan view, the length of one side is, for example, 50 μm or more and 2,000 μm or less.

The semiconductor part 10 is composed of nitride semiconductor layers. A nitride semiconductor includes a semiconductor of all compositions obtained by varying the composition ratios x and y within their ranges in the chemical formula InₓAl_{y}Ga_{1-x-y}N (0≤x≤1, 0≤y≤1, x+y≤1).

The semiconductor part 10 has a recess R. For example, the recess R is located near the center of the semiconductor part 10 in a plan view. The recess R is defined by lateral surfaces of the first semiconductor layer 10n, lateral surfaces of the light-emitting layer 10a, lateral surfaces of the second semiconductor layer 10p, and a lower surface of the first semiconductor layer 10n. Among the surfaces defining the recess R, the lateral surfaces of the first semiconductor layer 10n, the lateral surfaces of the light-emitting layer 10a, and the lateral surfaces of the second semiconductor layer 10p are inclined surfaces inclined with respect to the upper surface 10c. The upper surface 10c is roughened. The arithmetic average roughness Ra of the upper surface 10c is, for example, 100 nm or more and 250 nm or less.

The first semiconductor layer 10n has an exposed portion S exposed through the second semiconductor layer 10p and the light-emitting layer 10a. The height from the upper surface 10c to the exposed portion S is substantially the same as the height from the upper surface 10c to the surface of the first semiconductor layer 10n defining the recess R. The exposed portion S is located around the second semiconductor layer 10p and the light-emitting layer 10a.

A portion of the semiconductor part 10 from the upper surface 10c to the exposed portion S is constituted by the first semiconductor layer 10n. The lateral surfaces of the first semiconductor layer 10n are inclined surfaces inclined with respect to the upper surface 10c. The semiconductor part 10 has a layered body including the light-emitting layer 10a and the second semiconductor layer 10p, which are located under the first semiconductor layer 10n. The lateral surfaces of the layered body are inclined surfaces inclined with respect to the upper surface 10c.

A p-side electrode 12 is disposed on the lower surface of the second semiconductor layer 10p. The p-side electrode 12 is electrically connected to the second semiconductor layer 10p. The p-side electrode 12 has a reflectance of 60% or more and preferably 70% or more with respect to light having a peak wavelength emitted from the light-emitting layer 10a. With this configuration, light traveling from the light-emitting layer 10a toward the second semiconductor layer 10p can be reflected by the p-side electrode 12 toward the first semiconductor layer 10n, and thus light extraction efficiency can be improved. As a metal material of the p-side electrode 12, a metal material such as Ag, Al, Rh, Ni, Ti, or Pt, an alloy containing any of these materials as a main component, or the like can be used. The p-side electrode 12 may have a single-layer structure formed of one of these metal materials, or a layered structure in which a plurality of layers are layered. Alternatively, as the p-side electrode 12, a light-transmissive electrically conductive film such as an indium tin oxide (ITO) film, a zinc oxide (ZnO) film, or indium oxide (In₂O₃) can be used.

A first insulating film 15 is disposed on the second semiconductor layer 10p and the p-side electrode 12. The first insulating film 15 has an opening from which a portion of the p-side electrode 12 is exposed. For example, the first insulating film 15 is a silicon oxide film or a silicon nitride film.

A second insulating film 16 is disposed on the lateral surfaces of the second semiconductor layer 10p, the lateral surfaces of the light-emitting layer 10a, and the first insulating film 15. The second insulating film 16 is disposed on the exposed portion S and lateral surfaces of the first insulating layer 10n. The second insulating film 16 has an opening from which a portion of the p-side electrode 12 is exposed, and an opening that is located in the recess R and from which a portion of the lower surface of the first insulating layer 10n is exposed. The second insulating film 16 is, for example, a silicon oxide film or a silicon nitride film.

A first electrically-conductive member 14 is disposed under the second insulating film 16. The first electrically-conductive member 14 is electrically connected to the first semiconductor layer 10n in the opening of the second insulating film 16 located in the recess R.

A second electrically-conductive member 13 is disposed under the second insulating film 16. The second electrically-conductive member 13 is electrically connected to the p-side electrode 12 exposed through the opening of the first insulating film 15 and the opening of the second insulating film 16. The second electrically-conductive member 13 is electrically connected to the second semiconductor layer 10p via the p-side electrode 12.

As a material of each of the first electrically-conductive member 14 and the second electrically-conductive member 13, a metal material or a semiconductor material, such as Al, Rh, Ag, Ti, Pt, Au, Cu, or Si, or an alloy containing any of these materials as a main component can be used. Each of the first electrically-conductive member 14 and the second electrically-conductive member 13 may have a single-layer structure formed of one of these metal materials, or a layered structure in which a plurality of layers are layered. The first electrically-conductive member 14 and the second electrically-conductive member 13 may be formed of the same material and have the same structure, or may be formed of different materials and have different structures.

The dielectric film 22 is disposed on the upper surface 10c of the semiconductor part 10, and includes an oxide. The refractive index of the dielectric film 22 is lower than the refractive index of the semiconductor part 10 and is closer to the refractive index of the light-transmissive member 23 than to the refractive index of the semiconductor part 10. That is, the refractive index of the dielectric film 22 is lower than the refractive index of the semiconductor part 10, and the absolute value of the difference between the refractive index of the dielectric film 22 and the refractive index of the light-transmissive member 23 is less than the absolute value of the difference between the refractive index of the dielectric film 22 and the refractive index of the semiconductor part 10. For example, the refractive index of the semiconductor part 10 is 2.0 or more and 3.0 or less, the refractive index of the light-transmissive member 23 is 1.7 or more and 1.9 or less, and the refractive index of the dielectric film 22 is 1.7 or more and 1.9 or less. The absolute value of the difference between the refractive index of the dielectric film 22 and the refractive index of the light-transmissive member 23 is, for example, 0.3 or less, preferably 0.2 or less, and more preferably 0.1 or less. The term “refractive index” as used in the present embodiment refers to a refractive index at the peak wavelength of light emitted from the light-emitting layer 10a of the semiconductor part 10. The oxide contains Al and Ta. When the sum of the Al content (first content) in the oxide and the Ta content (second content) in the oxide is taken as 100 atomic %, the Ta content (second content) is greater than 0 atomic % and less than or equal to 60 atomic %. The thickness of the dielectric film 22 is, for example, 1 μm or more and 50 μm or less.

The dielectric film 22 is preferably a dielectric film formed of an inorganic material. The dielectric film 22 is light-transmissive and transmits light emitted from the light-emitting layer 10a of the semiconductor part 10. The dielectric film 22 has a transmittance of 60% or more and preferably 70% or more with respect to light having a peak wavelength emitted from the light-emitting layer 10a. The dielectric film 22 preferably includes a film having a refractive index between the refractive index of the semiconductor part 10 and the refractive index of the light-transmissive member 23 described below. With this configuration, high light extraction efficiency can be obtained. For example, the dielectric film 22 includes a film having a refractive index lower than the refractive index of the semiconductor part 10. For example, the refractive index of the dielectric film 22 is lower than the refractive index of the semiconductor part 10 and higher than the refractive index of the light-transmissive member 23. In a case where the semiconductor part 10 includes a plurality of semiconductor layers, the refractive index of the semiconductor part 10 refers to the refractive index of a semiconductor layer contacting the dielectric film 22. In the present embodiment, the refractive index of the dielectric film 22 is lower than the refractive index of the first semiconductor layer 10n.

The light-transmissive member 23 is disposed on an upper surface 22a of the dielectric film 22. For the light-transmissive member 23, a sintered body of a phosphor, a resin (binder) such as an epoxy resin or a silicone resin containing a phosphor, or the like can be used. The sintered body of the phosphor refers to a member obtained by sintering only the phosphor or a member obtained by sintering the phosphor together with a ceramic such as aluminum oxide, aluminum nitride, silicon nitride, silicon carbide, zirconium oxide, or titanium oxide, and refers to a member that does not contain a resin. When the sintered body of the phosphor is used for the light-transmissive member 23, the heat dissipation of the phosphor can be improved as compared to when the resin (binder) containing the phosphor is used, and thus a decrease in wavelength conversion efficiency can be reduced. Examples of the phosphor that can be used include yttrium aluminum garnet based phosphors (for example, Y₃(Al, Ga)₅O₁₂:Ce), lutetium aluminum garnet based phosphors (for example, Lu₃(Al, Ga)₅O₁₂:Ce), terbium aluminum garnet based phosphors (for example, Tb₃(Al, Ga)₅O₁₂:Ce), nitride based phosphors such as β-SiAlON based phosphors (for example, (Si, Al)₃(O, N)₄:Eu), α-SiAlON based phosphors (for example, Ca(Si, Al)₁₂(O, N)₁₆:Eu), CASN based phosphors (for example, CaAlSiN₃:Eu), SCASN based phosphors (for example, (Sr,Ca)AlSiN₃:Eu), fluoride based phosphors such as KSF based phosphors (for example, K₂SiF₆:Mn), KSAF based phosphors (for example, K₂(Si,Al)F₆:Mn), and MGF based phosphors (for example, 3.5MgO.0.5MgF₂.GeO₂:Mn), phosphors having a Perovskite structure (for example, CsPb(F,Cl,Br,I)₃), and quantum dot phosphors (for example, CdSe, InP, AgInS₂, and AgInSe₂). For example, the dielectric film 22 includes a film having a refractive index higher than the refractive index of the light-transmissive member 23. The thickness of the light-transmissive member 23 is, for example, 100 μm or more and 400 μm or less, preferably 120 μm or more and 300 μm or less, and more preferably 130 μm or more and 260 μm or less. The light-transmissive member 23 may be a light-transmissive substrate such as a sapphire substrate.

In the following, investigations conducted by the inventor of the present application on the compositions of dielectric films will be described.

The inventor of the present application has investigated the relationship between the composition of each of dielectric films and the bonding strength between each of the dielectric films and a corresponding light-transmissive member. In this investigation, as light-transmissive members, plate-shaped sintered bodies each formed of a yttrium aluminum garnet based phosphor (hereinafter also referred to as a YAG plate) and having a thickness of 400 μm, and sapphire substrates each having a thickness of 850 μm were prepared. Then, dielectric films indicated in Table 1 below were formed on the light-transmissive members by a sputtering method or a chemical vapor deposition (CVD) method. A value (unit: at %) in parentheses in the material column in Table 1 is a value converted into the percentage of a metal element.

TABLE 1

| | MATERIAL |
|---|---|
| DIELECTRIC FILM D1 | SiO₂ |
| DIELECTRIC FILM D2 | SiON |
| DIELECTRIC FILM D3 | SiN |
| DIELECTRIC FILM D4 | Al₂O₃ |
| DIELECTRIC FILM D5 | Nb₂O₅(40 at %) + SiO₂(60 at %) |
| DIELECTRIC FILM D6 | Al₂O₃(75 at %) + Nb₂O₅(25 at %) |
| DIELECTRIC FILM D7 | Al₂O₃(65 at %) + Ta₂O₅(35 at %) |

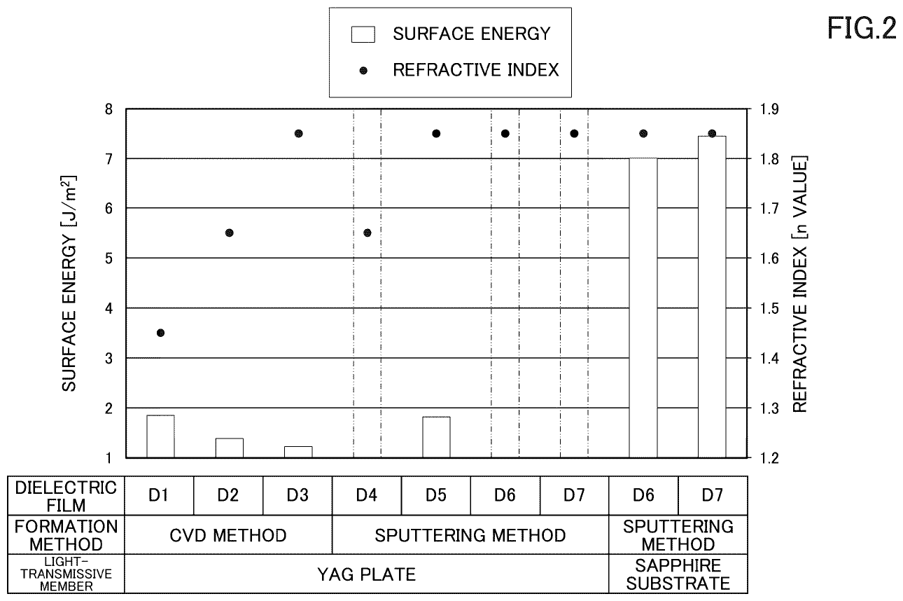

Then, the dielectric films were heated to 300° C. to simulate reflow at a time when a light-emitting device is mounted on a mounting substrate. After the temperature was lowered to room temperature, the dielectric films were peeled off from the light-transmissive members. When dielectric films were peeled off from the light-transmissive members, the surface energy of each of the surfaces of the dielectric films in contact with the light-transmissive members was measured. The results are illustrated in FIG. 2. In three samples in which dielectric films D4, D6, and D7 were formed on YAG plates by the sputtering method, the light-transmissive members cracked before the dielectric films were peeled off from the light-transmissive members and thus the surface energy was unable to be measured. The surface energy of each of the three samples was considered to be higher than 8 J/cm². In FIG. 2, the refractive index (n value) of each of the dielectric films is also illustrated.

As illustrated in FIG. 2, high surface energy was obtained in the dielectric films D4, D6, and D7. Further, the refractive indices of the dielectric films D6 and D7 were higher than the refractive index of the dielectric film D4. Therefore, the dielectric films D6 and D7 are promising from the viewpoint of bonding strength and refractive index.

The inventor of the present application has investigated the relationship between the composition and the transmittance of each dielectric film. In this investigation, sapphire substrates each having a thickness of 850 μm were prepared as light-transmissive members, and dielectric films indicated in Table 2 below were formed on the light-transmissive members. The thicknesses of the dielectric films were 1 μm. A value (unit: at %) in parentheses in the material column in Table 2 is a value converted into the percentage of a metal element.

TABLE 2

| | MATERIAL |
|---|---|
| DIELECTRIC FILM D1 | SiO₂ |
| DIELECTRIC FILM D4 | Al₂O₃ |
| DIELECTRIC FILM D5 | Nb₂O₅(40 at %) + SiO₂(60 at %) |
| DIELECTRIC FILM D6 | Al₂O₃(75 at %) + Nb₂O₅(25 at %) |
| DIELECTRIC FILM D7 | Al₂O₃(65 at %) + Ta₂O₅(35 at %) |
| DIELECTRIC FILM D8 | Ta₂O₅ |
| DIELECTRIC FILM D9 | Al₂O₃(75 at %) + TiO₂(25 at %) |

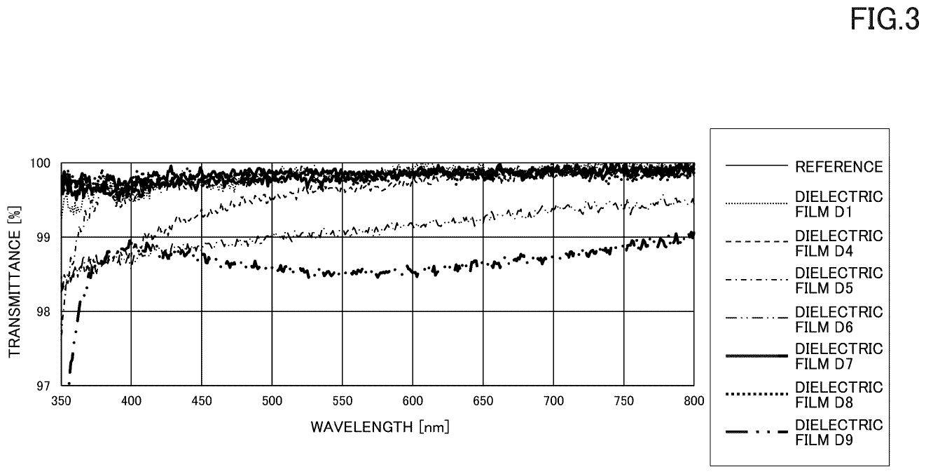

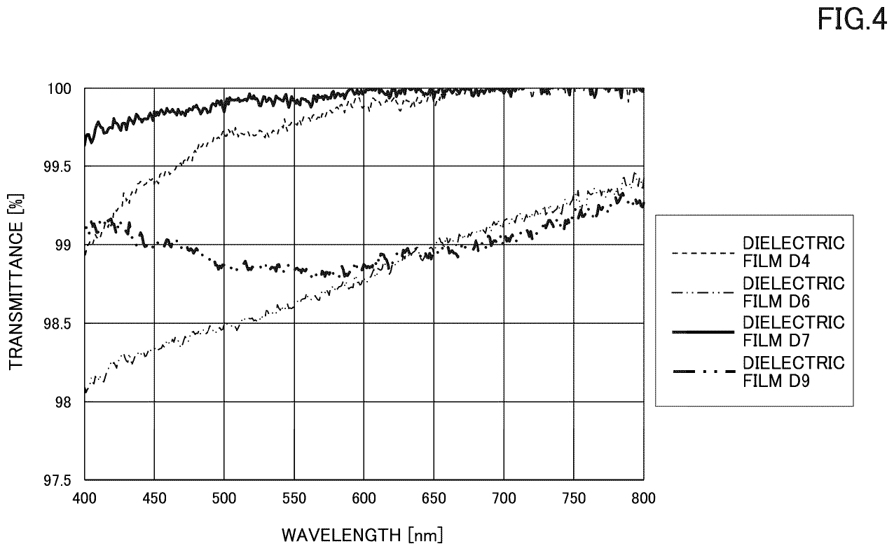

The transmittance of each of the dielectric films was measured. The results are illustrated in in FIG. 3 and FIG. 4. The measurement result of the transmittance of a sapphire substrate on which no dielectric film was formed is also illustrated in FIG. 3 as a reference.

As illustrated in FIG. 3, dielectric films D1, D5, D7, and D8 had transmittances comparable to the transmittance of the reference in a wide wavelength range including the wavelength of blue light at about 460 nm. Further, as illustrated in FIG. 4, in a wavelength range of 400 nm to 800 nm, the transmittance of the dielectric film D7 was the highest among the dielectric films D4, D6, D7, and D9 each containing Al. Therefore, the dielectric film D7 is promising from the viewpoint of transmittance.

In general, a metal oxide has a higher light transmittance as the band gap is larger. Therefore, among Al₂O₃, Ta₂O₅, Nb₂O₅, and TiO₂, the transmittance decreases in the order of Al₂O₃, Ta₂O₅, Nb₂O₅, and TiO₂. Based on this general knowledge, the transmittance of a composite oxide of Al₂O₃ and Ta₂O₅, the transmittance of a composite oxide of Al₂O₃ and Nb₂O₅, and the transmittance of a composite oxide of Al₂O₃ and TiO₂ are lower than the transmittance of Al₂O₃.

However, as illustrated in FIG. 3 and FIG. 4, the dielectric film D7 formed of the composite oxides of Al₂O₃ and Ta₂O₅ had a higher transmittance than the transmittance of the dielectric film D4 formed of Al₂O₃. That is, results different from the above general knowledge were obtained. The reason for this is not clear, but it is presumed that the dielectric film D7 was densely formed due to the surfactant effect of Ta₂O₅ in the composite oxide, and scattering of light in the dielectric film D7 was suppressed.

Conversely, as illustrated in FIG. 3 and FIG. 4, the dielectric film D6 formed of the composite oxides of Al₂O₃ and Nb₂O₅ and the dielectric film D9 formed of the composite oxides of Al₂O₃ and TiO₂ had lower transmittances than the transmittance of the dielectric film D4. It is considered that this is because the band gap of each of the Nb₂O₅ and TiO₂ is smaller than the band gap of Al₂O₃, and also because no surfactant effect was exhibited and the films that are more sparse than the dielectric film D7 were formed.

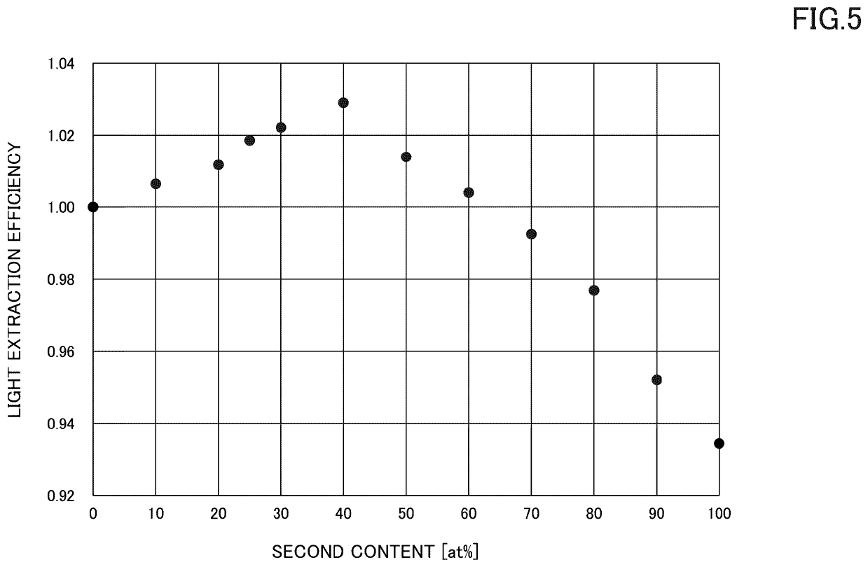

Based on results of such investigations, the inventor of the present application has investigated the relationship between light extraction efficiency and the ratio of Al and Ta contained in an oxide. In this investigation, the structure of the light-emitting device 1 according to the first embodiment illustrated in FIG. 1 was used as a model, and changes in light extraction efficiency when the ratio of Al and Ta in the dielectric film 22 was changed were simulated. In this simulation, the Ta content (second content) was changed when the sum of the Al content (first content) in the oxide and the Ta content (second content) in the oxide was taken as 100 atomic %, and light extraction efficiency was calculated. The refractive index of the semiconductor part 10 was set to 2.4, and the refractive index of the light-transmissive member 23 was set to 1.83. The results are illustrated in FIG. 5. Light extraction efficiency on the vertical axis in FIG. 5 is a value normalized by light extraction efficiency when the second content is 0 atomic %.

As illustrated in FIG. 5, the results indicated that when the second content was greater than 0 atomic % and less than or equal to 60 atomic %, the light extraction efficiency was higher than 1.00. As described above, based on the general knowledge, the transmittance of the composite oxide of Al₂O₃ and Ta₂O₅, the transmittance of the composite oxide of Al₂O₃ and Nb₂O₅, and the transmittance of the composite oxide of Al₂O₃ and TiO₂ are lower than the transmittance of Al₂O₃. The inventor of the present application has found that the light extraction efficiency increases when the second content is greater than 0 atomic % and less than or equal to 60 atomic % than when the second content is 0 atomic %. This finding is not known to date, and has been newly found by the inventor of the present application.

In the measurement results illustrated in FIG. 3, the dielectric film D8 formed of Ta₂O₅ had a high transmittance. However, the dielectric film D8 corresponds to a dielectric film whose second content is 100 atomic % in the above simulation, and thus the 1 light extraction efficiency is low. It is considered that this is because the refractive index of Ta₂O₅ is about 2.2, and the refractive index of the dielectric film D8 is closer to the refractive index (about 2.4) of the semiconductor part 10 than to the refractive index (about 1.75 to 1.85) of the light-transmissive member 23.

The present embodiment is based on these findings, and the refractive index of the dielectric film 22 is lower than the refractive index of the semiconductor part 10 and is closer to the refractive index of the light-transmissive member 23 than to the refractive index of the semiconductor part 10. Further, the oxide included in the dielectric film 22 contains Al and Ta, and when the sum of the Al content (first content) in the oxide and the Ta content (second content) in the oxide is taken as 100 atomic %, the second content is greater than 0 atomic % and less than or equal to 60 atomic %. Therefore, both improvement of light extraction efficiency and improvement of the bonding strength between the light-transmissive member and the dielectric film can be achieved. The first content and the second content can be measured by energy dispersive X-ray analysis (EDX).

Particularly high bonding strength is obtained when the second content is greater than 0 atomic % and less than 25 atomic %. In addition, particularly high light extraction efficiency is obtained when the second content is 25 atomic % or more and 60 atomic % or less, preferably 30 atomic % or more and 50 atomic % or less, and more preferably 35 atomic % or more and 45 atomic % or less.

The arithmetic average roughness Ra of the upper surface 10c of the semiconductor part 10 is preferably 100 nm or more and 250 nm or less. When the arithmetic average roughness Ra of the upper surface 10c is 100 nm or more and 250 nm or less, a region having a refractive index lower than the refractive index of the semiconductor part 10 and higher than the refractive index of the dielectric film 22 is present in the vicinity of the boundary between the semiconductor part 10 and the dielectric film 22, and a change in refractive index in a light emission direction becomes gentle. Therefore, the light extraction efficiency can be further improved.

The refractive index of the dielectric film 22 is preferably higher than the refractive index of the light-transmissive member 23. When the refractive index of the dielectric film 22 is higher than the refractive index of the light-transmissive member 23, the refractive index decreases in the order of the semiconductor part 10, the dielectric film 22, and the light-transmissive member 23 along the light emission direction, and thus the light extraction efficiency can be further improved.

The content of Ta in the dielectric film 22 is preferably larger in the lower surface side of the dielectric film 22 than in the upper surface side of the dielectric film 22. When the content of Ta in the dielectric film 22 is larger in the lower surface side of the dielectric film 22 than in the upper surface side of the dielectric film 22, the light extraction efficiency can be further improved. In particular, as illustrated in FIG. 5, this is effective when the second content is 40 atomic % or less.

For example, the light-emitting layer is configured to emit light having a peak emission wavelength in a range of 350 nm to 500 nm. For example, when the phosphor contained in the light-transmissive member 23 converts light (blue light) having a peak emission wavelength in a range of 350 nm to 500 nm into light (yellow light) having a peak emission wavelength in a range of 565 nm to 590 nm, the light-emitting device 1 can emit white light.

The dielectric film 22 may include a plurality of films. For example, the dielectric film 22 may include: a first dielectric film such as a SiON film in contact with the semiconductor part 10; and a second dielectric film disposed between the first dielectric film and the light-transmissive member 23 and including an oxide containing Al and Ta. In the light-emitting device 1 including the dielectric film 22 that includes a plurality of films, both improvement of light extraction efficiency and improvement of bonding strength can be achieved.

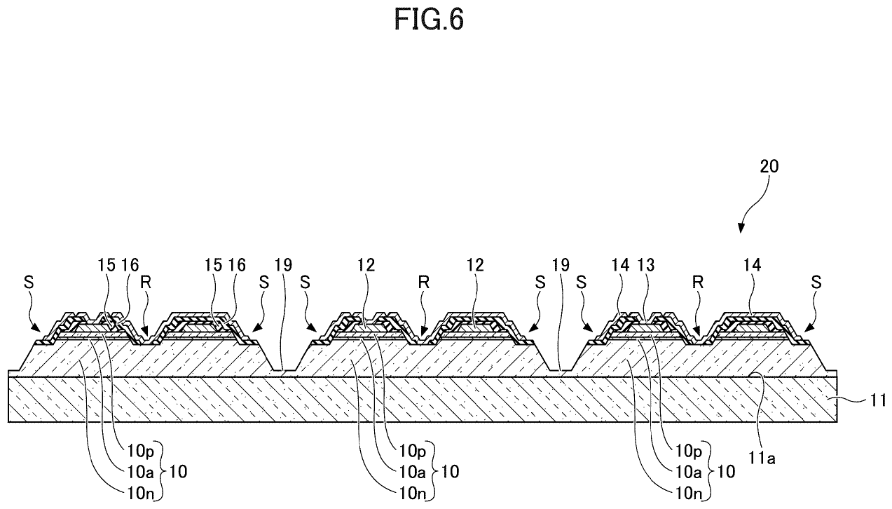

Subsequently, a method of manufacturing the light-emitting device according to the first embodiment will be described. FIG. 6 to FIG. 13 are cross-sectional views illustrating the method of manufacturing the light-emitting device according to the first embodiment.

First, as illustrated in FIG. 6, a wafer 20 is prepared. The wafer 20 includes a substrate 11, a plurality of semiconductor parts 10, a p-side electrode 12, a first insulating film 15, a second insulating film 16, a first electrically-conductive member 14, and a second electrically-conductive member 13. The substrate 11 has a main surface 11a. The plurality of semiconductor parts 10 are arranged on the main surface 11a so as to be separated from each other. The thickness of the substrate 11 is, for example, 500 μm or more and 1,000 μm or less.

The plurality of semiconductor parts 10 are formed, for example, as follows. That is, after a semiconductor structure including a first semiconductor layer 10n, a light-emitting layer 10a, and a second semiconductor layer 10p is disposed on the substrate 11, a resist mask is formed on regions of the semiconductor structure where the plurality of semiconductor parts 10 are to be formed. Subsequently, a portion of the semiconductor structure is removed by using the resist mask. In this manner, the plurality of semiconductor parts 10 can be formed. For example, reactive ion etching (RIE) can be used to remove a portion of the semiconductor structure.

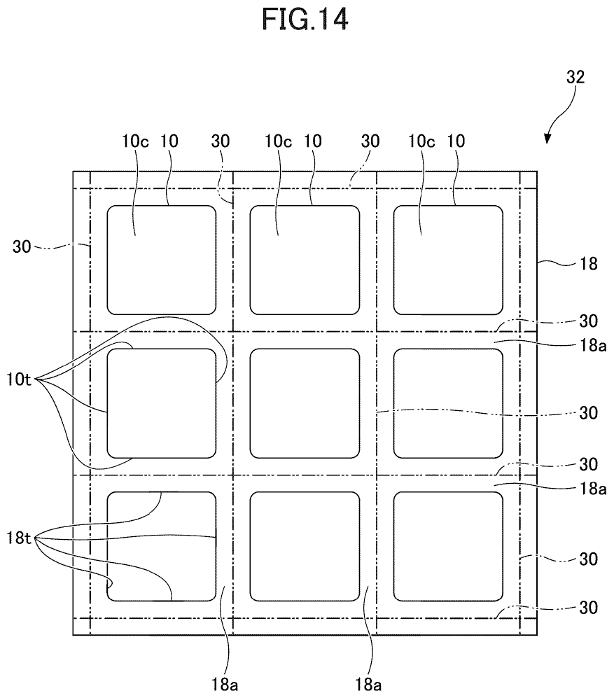

As will be described later with reference to FIG. 14, the plurality of semiconductor parts 10 are arranged in a matrix on the main surface 11a in a plan view. In this specific example, adjacent semiconductor parts 10 of the plurality of semiconductor parts 10 are connected to each other via a connection portion 19. Similar to the plurality of semiconductor parts 10, the connection portion 19 is disposed on the main surface 11a. The connection portion 19 is continuous with the first semiconductor layer 10n and is formed of a semiconductor layer including an n-type semiconductor. The connection portion 19 is, for example, a portion of a semiconductor layer including an n-type semiconductor that is left without being removed when the semiconductor structure is removed in a process of forming the plurality of semiconductor parts 10 described above. The connection portion 19 does not have to be formed.

For example, the semiconductor parts 10 are formed by a metal organic chemical vapor deposition (MOCVD) method. In the forming of the semiconductor parts 10, the first semiconductor layer 10n, the light-emitting layer 10a, and the second semiconductor layer 10p are formed in this order on the main surface 11a. Recesses R and exposed portions S can be formed by, for example, forming a resist mask in a region of the semiconductor parts 10 excluding regions where the recesses R and the exposed portions S are to be formed, and then removing a portion of nitride semiconductor layers by using the resist mask. After nitride semiconductor layers are layered on the substrate 11 and recesses R and exposed portions S are formed in regions where the plurality of semiconductor parts 10 are to be formed, the nitride semiconductor layers may be separated so as to obtain the plurality of semiconductor parts 10.

The p-side electrode 12 can be formed by, for example, the sputtering method, a vapor deposition method, or the like. The first insulating film 15 can be formed by, for example, the sputtering method, the vapor deposition method, or the like. After the first insulating film 15 is formed, an opening can be formed in the first insulating film 15 by removing a portion of the first insulating film 15. A portion of the first insulating film 15 can be removed by, for example, wet etching, dry etching, or the like. The second insulating film 16 can be formed by, for example, the sputtering method or the vapor deposition method. After the second insulating film 16 is formed, an opening can be formed in the second insulating film 16 by removing a portion of the second insulating film 16. A portion of the second insulating film 16 can be removed by, for example, wet etching, dry etching, or the like. The first electrically-conductive member 14 and the second electrically-conductive member 13 can be formed by, for example, the sputtering method, the vapor deposition method, or the like.

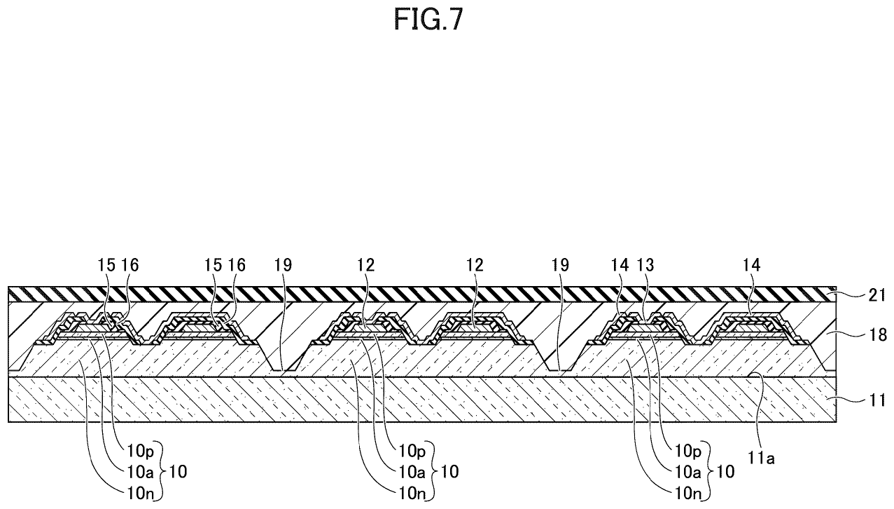

Subsequently, as illustrated in FIG. 7, a resin member 18 is disposed on the wafer 20. For example, after the resin member 18 is disposed on a support substrate 21, the wafer 20 and the support substrate 21 are bonded to each other via the resin member 18 in a state in which the resin member 18 is positioned between the substrate 11 and the support substrate 21. By performing such a process, the resin member 18 is formed so as to cover lateral surfaces of the semiconductor parts 10, the second insulating film 16, the first electrically-conductive member 14, and the second electrically-conductive member 13. The resin member 18 is also disposed between two adjacent semiconductor parts 10 of the plurality of semiconductor parts 10. That is, the resin member 18 is disposed on the main surface 11a of the substrate 11. In the example of FIG. 7, the resin member 18 is disposed on the main surface 11a via the connection portion 19. However, if the connection portion 19 is not disposed, the resin member 18 is disposed in contact with the main surface 11a of the substrate 11. For example, an epoxy resin, an acrylic resin, a polyimide resin, or the like can be used for the resin member 18.

The support substrate 21 is disposed on the resin member 18, and the support substrate 21 is bonded to the resin member 18. For example, a sapphire substrate, a silicon substrate, or the like can be used for the support substrate 21.

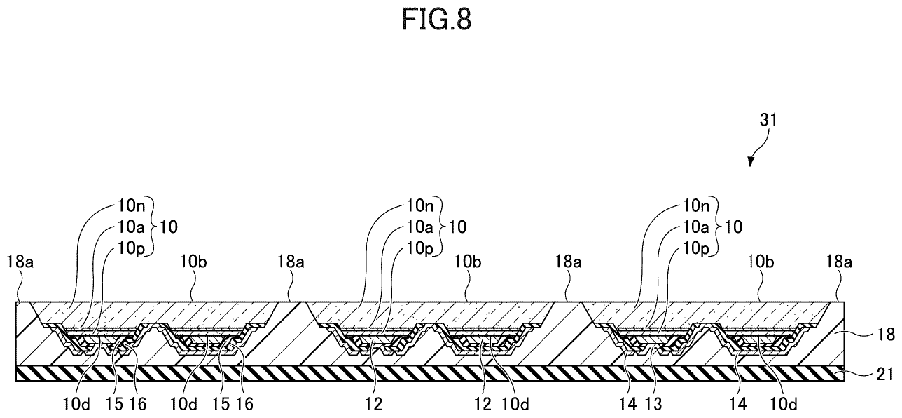

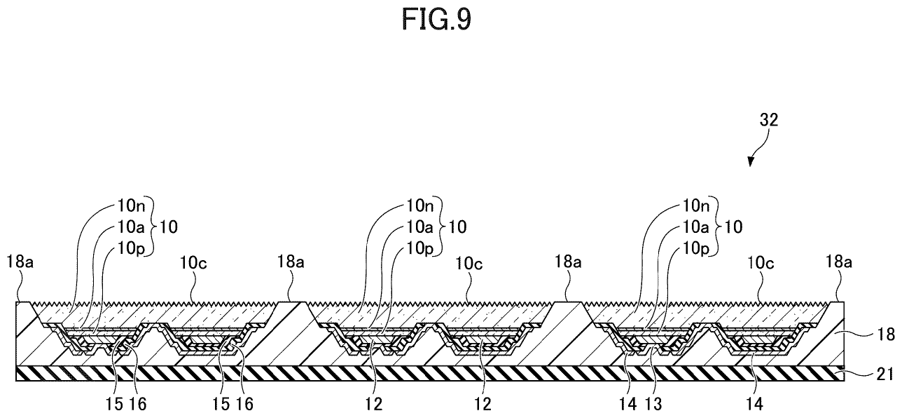

Subsequently, as illustrated in FIG. 8, the substrate 11 is removed from the wafer 20 on which the resin member 18 and the support substrate 21 are disposed. In the present embodiment, after the substrate 11 is removed, the connection portion 19 illustrated in FIG. 6 and FIG. 7 is removed by removing a portion of the first semiconductor layer 10n, and a portion of each of the semiconductor parts 10 and a portion of the resin member 18 are exposed. The state illustrated in FIG. 8 is upside down from the states illustrated in FIG. 6 and FIG. 7. In FIG. 7, the semiconductor parts 10 are arranged under the support substrate 21, whereas in FIG. 8, the semiconductor parts 10 are arranged above the support substrate 21. Similarly, the states illustrated in FIG. 9 to FIG. 13 described later are upside down from the states illustrated in FIG. 6 and FIG. 7.

A method such as laser lift-off (LLO), grinding, polishing, or etching is used to remove the substrate 11. In a case where the substrate 11 is a sapphire substrate, the substrate 11 is preferably removed by LLO. Each of the semiconductor parts 10 after the removal of the substrate 11 has a first surface 10d facing the support substrate 21 and a second surface 10b located on the opposite side of the first surface 10d. The second surface 10b is an exposed surface of each of the semiconductor parts 10 exposed by removing the substrate 11. An exposed surface of the resin member 18 exposed by removing a portion of the semiconductor parts 10 is referred to as a resin upper surface 18a.

In this manner, an intermediate member 31 including the support substrate 21, the resin member 18, and the plurality of semiconductor parts 10 is obtained.

Subsequently, as illustrated in FIG. 9, the second surface 10b is roughened. By performing this roughening process, an intermediate member 32 including the semiconductor parts 10 each having a roughened upper surface 10c is formed. The light extraction efficiency of the light-emitting device can be improved by roughening the second surface 10b to obtain the upper surface 10c, which is a main light extraction surface of each of the semiconductor parts 10. For example, RIE using a chlorine-containing gas or wet etching using an alkaline solution such as tetramethyl ammonium hydroxide (TMAH) can be used to roughen the second surface 10b. The arithmetic average roughness Ra of the second surface 10b before the roughening process is performed is, for example, 0.1 nm or more and 0.5 nm or less. The arithmetic average roughness Ra of the upper surface 10c after the roughening process is performed is, for example, 100 nm or more and 250 nm or less.

As described above, the second surface 10b is preferably roughened, but does not have to be roughened. By omitting the roughening process of the second surface 10b, a process of manufacturing the light-emitting device can be shortened.

FIG. 14 is a plan view illustrating the method of manufacturing the light-emitting device according to the first embodiment. FIG. 14 illustrates a state after the above-described roughening process of the second surface 10b is performed. In FIG. 14, the intermediate member 32 in which the roughened upper surface 10c is exposed is depicted. As illustrated in FIG. 14, the semiconductor parts 10 each having the exposed upper surface 10c are arranged in a matrix. The resin member 18 is disposed between adjacent semiconductor parts of the plurality of semiconductor parts 10, and the resin upper surface 18a is exposed through the semiconductor parts 10.

In a plan view, the outer periphery of the upper surface 10c of each of the plurality of semiconductor parts 10 is referred to as an outer periphery 10t. In this example, the outer periphery 10t has a substantially rectangular shape. The end portion of the resin upper surface 18a overlapping the outer periphery 10t in a plan view is referred to as a resin end portion 18t.

A singulation line 30 is set between semiconductor parts 10 adjacent to each other in a plan view. The singulation line 30 is an imaginary line set to cleave a light-transmissive member 23 and a dielectric film 22, which will be described later, and to singulate these into a plurality of light-emitting devices 1. A plurality of singulation lines 30 are set along two directions orthogonal to each other.

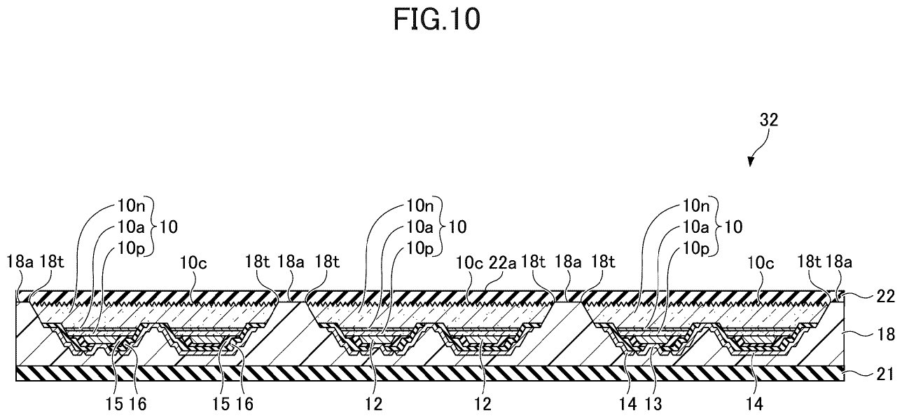

Subsequently, as illustrated in FIG. 10, a dielectric film 22 is formed so as to continuously cover portions of the semiconductor parts 10 and portions of the resin member 18. The dielectric film 22 can be formed by, for example, the sputtering method. The dielectric film 22 is formed so as to cover the upper surface 10c of each of the semiconductor parts 10, the resin upper surface 18a of the resin member 18, and lateral surfaces of the resin member 18 extending from the resin end portion 18t to the resin upper surface 18a. The thickness of the dielectric film 22 is, for example, 1 μm or more and 50 μm or less. This makes it possible to secure a sufficient arithmetic average roughness Ra while shortening the time required for a process of making the upper surface of the dielectric film 22 nearly flat, which will be described later. FIG. 10 illustrates the state of the dielectric film 22 after the process of making the upper surface of the dielectric film 22 nearly flat, which will be described later, is performed. The arithmetic average roughness Ra of the upper surface of the dielectric film 22 before the process of making the upper surface of the dielectric film 22 nearly flat is performed is greater than the arithmetic average roughness Ra of the upper surface of the dielectric film 22 after the process of making the upper surface of the dielectric film 22 nearly flat is performed.

After the dielectric film 22 is formed, the upper surface of the dielectric film 22 is made nearly flat. As a method of making the upper surface of the dielectric film 22 nearly flat, for example, chemical mechanical polishing (CMP) can be used. The arithmetic average roughness Ra of the upper surface of the dielectric film 22 before the process of making the upper surface of the dielectric film 22 nearly flat is performed is, for example, 50 nm or more and 200 nm or less. The arithmetic average roughness Ra of the upper surface of the dielectric film 22 after the process of making the upper surface of the dielectric film 22 nearly flat is performed is, for example, 0.1 nm or more and 0.5 nm or less. As used herein, “making a surface nearly flat” means making the arithmetic average roughness Ra of the surface close to 0.

The upper surface 22a of the dielectric film 22 can be made nearly flat by polishing away approximately one-third of the thickness of the formed film. For example, after the dielectric film 22 is formed with a thickness of approximately 10 μm, the dielectric film 22 having a thickness of approximately 10 μm has approximately 3 μm polished away, thereby making the upper surface 22a nearly flat.

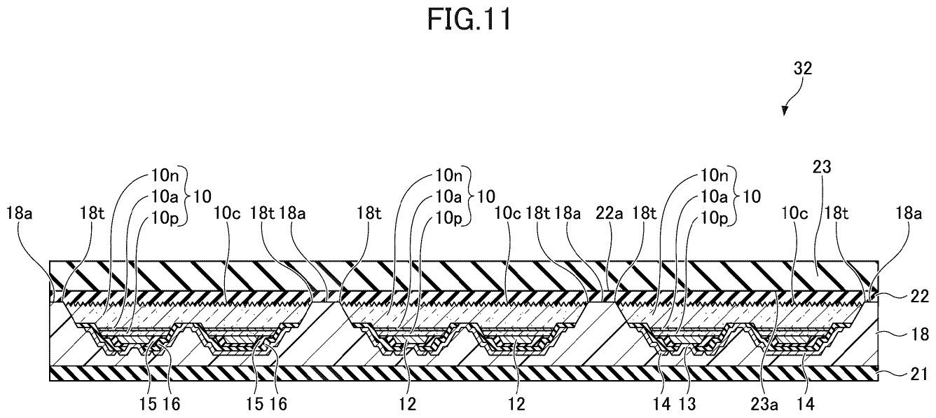

Subsequently, as illustrated in FIG. 11, a light-transmissive member 23 is disposed on the upper surface 22a, which is made nearly flat, of the dielectric film 22. The light-transmissive member 23 is directly bonded to the upper surface 22a, which is made nearly flat, of the dielectric film 22. The light-transmissive member 23 has a third surface 23a facing the upper surface 22a of the dielectric film 22.

For example, surface activated bonding (SAB) can be used to directly bond the dielectric film 22 and the light-transmissive member 23 together. In SAB, after the upper surface 22a, which serves as a bonding surface of the dielectric film 22, and the third surface 23a, which serves as a bonding surface of the light-transmissive member 23, are activated by surface treatment, the dielectric film 22 and the light-transmissive member 23 are directly bonded together. As a method of activating the upper surface 22a of the dielectric film 22 and the third surface 23a of the light-transmissive member 23, for example, surface treatment by which the bonding surfaces are irradiated with an ion beam including ions such as Ar in a vacuum can be used. As compared to when an adhesive including a resin is used, for example, when the dielectric film 22 and the light-transmissive member 23 are directly bonded together, the light extraction efficiency can be improved without light absorption by an adhesive. In direct bonding, higher bonding strength can be obtained by applying a sufficient load between the upper surface 22a of the dielectric film 22 and the third surface 23a of the light-transmissive member 23. When the bonding surfaces are directly bonded together, it is preferable that the arithmetic average roughness Ra of each of the bonding surfaces is lower, for example, the arithmetic average roughness Ra of each of the bonding surfaces is 0.1 nm or more and 0.5 nm or less. In this manner, a sufficient load can be applied between the bonding surfaces, and the bonding surfaces can be bonded together with high bonding strength.

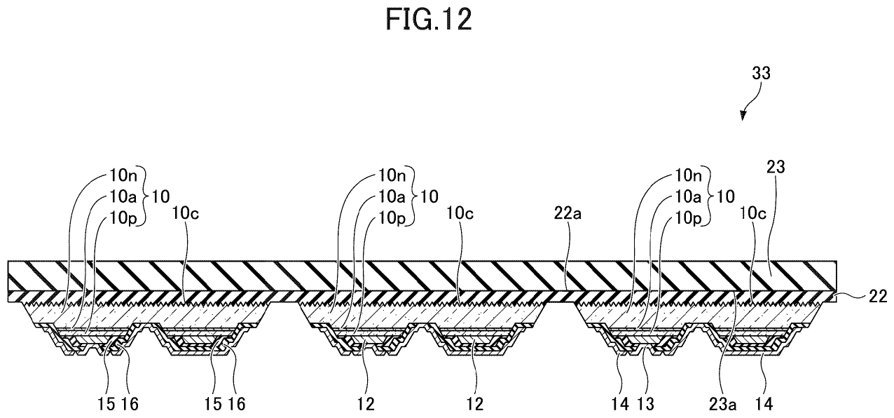

Subsequently, as illustrated in FIG. 12, the support substrate 21 and the resin member 18 are removed, and an intermediate member 33 in which the plurality of semiconductor parts 10 are bonded to one set of the dielectric film 22 and the light-transmissive member 23 is formed. For example, wet etching or the like is used to remove the resin member 18.

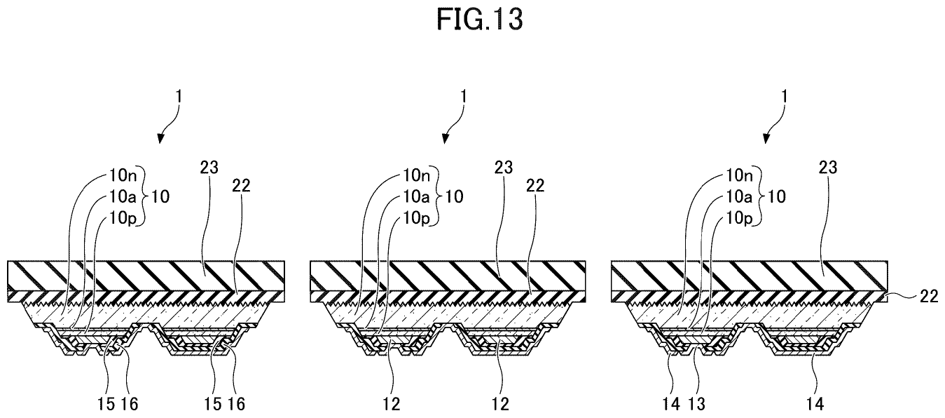

Subsequently, as illustrated in FIG. 13, the intermediate member 33 is cleaved and singulated into a plurality of light-emitting devices 1. Each of the plurality of light-emitting devices 1 includes a semiconductor part 10, a dielectric film 22, and a light-transmissive member 23. A method of cleaving the intermediate member 33 is not limited. For example, before the light-transmissive member 23 is disposed, the dielectric film 22 is irradiated with laser light so as to form a crack along each of the singulation lines 30, and the intermediate member can be cleaved with the crack being a starting point.

In this manner, the plurality of light-emitting devices 1 can be manufactured.

The dielectric film 22 may be formed by a bias sputtering method. A gap is less likely to be formed between the dielectric film 22 and each of the semiconductor parts 10 when the dielectric film 22 is formed by the sputtering method. However, a gap is even less likely to be formed when the dielectric film 22 is formed by the bias sputtering method.

The dielectric film 22 may include a plurality of films. For example, a SiON film may be formed as a first dielectric film so as to be in contact with the semiconductor parts 10 and the SiON film may be subjected to CMP, and a second dielectric film including an oxide containing Al and Ta may be formed so as to be in contact with the SiON film and the second dielectric film may be subjected to CMP. The light-emitting devices 1 each including the dielectric film 22 formed by the above method can also improve light extraction efficiency while improving bonding strength.

Instead of forming the dielectric film 22 so as to be in contact with the semiconductor parts 10, the dielectric film 22 may be formed on a surface of the light-transmissive member 23 opposite to a surface serving as the third surface 23a, and the dielectric film 22 may be bonded to the semiconductor parts 10 after the dielectric film 22 is subjected to CMP. In a case where the light transmissive member 23 is a sintered body, it is not easy to increase the flatness of the surface of the light-transmissive member 23 opposite to the surface serving as the third surface 23a. However, by forming the dielectric film 22 on this surface of the light-transmissive member 23 by the sputtering method, the bonding strength between the light transmissive member 23 and the dielectric film 22 can be improved as compared to direct bonding.

### Second Embodiment

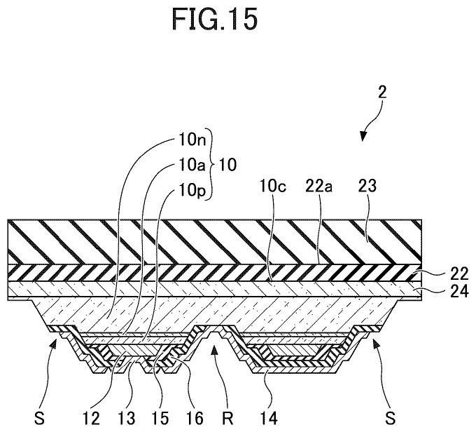

A second embodiment differs from the first embodiment mainly in that a light-transmissive member is provided between a semiconductor part 10 and a dielectric film 22. FIG. 15 is a cross-sectional view illustrating a light-emitting device according to the second embodiment.

A light-emitting device 2 according to the second embodiment includes the semiconductor part 10, a light-transmissive member 24 (hereinafter, also referred to as a first light-transmissive member 24), the dielectric film 22, and a light-transmissive member 23 (hereinafter, also referred to as a second light-transmissive member 23). The semiconductor part 10, the dielectric film 22, and the second light-transmissive member 23 have configurations the same as or similar to the configurations in the first embodiment. However, an upper surface 10c does not have to be roughened.

The first light-transmissive member 24 is disposed between the semiconductor part 10 and the dielectric film 22. The first light-transmissive member 24 has a refractive index lower than the refractive index of the semiconductor part 10 and closer to the refractive index of the dielectric film 22 than to the refractive index of the semiconductor part 10. That is, the refractive index of the first light-transmissive member 24 is lower than the refractive index of the semiconductor part 10, and the absolute value of the difference between the refractive index of the first light-transmissive member 24 and the refractive index of the dielectric film 22 is less than the absolute value of the difference between the refractive index of the first light-transmissive member 24 and the refractive index of the semiconductor part 10. The refractive index of the first light-transmissive member 24 is, for example, 1.7 or more and 1.9 or less, and preferably 1.7 or more and 1.8 or less. The thickness of the first light-transmissive member 24 is, for example, 10 μm or more and 50 μm or less, preferably 15 μm or more and 40 μm or less, and more preferably 25 μm or more and 35 μm or less.

Other configurations of the light-emitting device 2 are the same as or similar to those of the light-emitting device 1.

Similar to the first embodiment, according to the second embodiment, both improvement of light extraction efficiency and improvement of the bonding strength between the dielectric film 22 and the second light-transmissive member 23 can be achieved. The refractive index of the first light-transmissive member 24 can be made lower than the refractive index of the dielectric film 22 in order to improve the light extraction efficiency by reflecting return light from the second light-transmissive member 23. As the first light-transmissive member 24, for example, a light-transmissive substrate such as a sapphire substrate can be used.

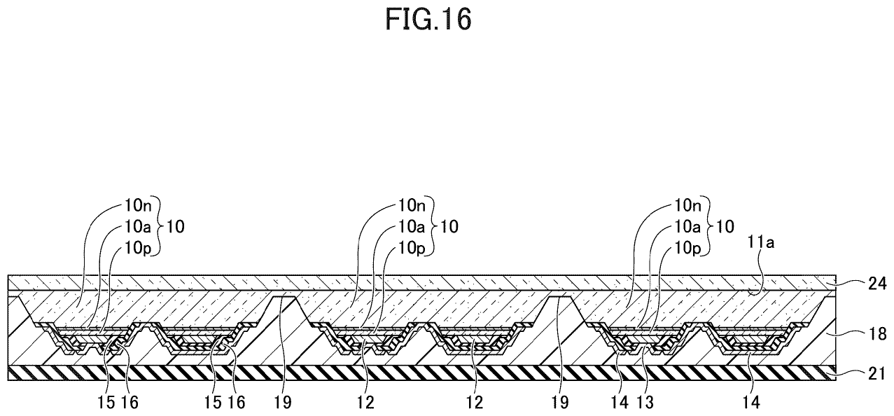

Subsequently, a method of manufacturing the light-emitting device according to the second embodiment will be described. FIG. 16 to FIG. 21 are cross-sectional views illustrating the method of manufacturing the light-emitting device according to the second embodiment.

First, similar to the first embodiment, a wafer 20 is prepared (see FIG. 6), and a resin member 18 is disposed on the wafer 20. A substrate 11 will serve as the first light-transmissive member 24 later, and is, for example, a sapphire substrate. For example, after the resin member 18 is disposed on a support substrate 21, the wafer 20 and the support substrate 21 are bonded to each other via the resin member 18 in a state in which the resin member 18 is positioned between the substrate 11 and the support substrate 21 (see FIG. 7).

Subsequently, as illustrated in FIG. 16, a main surface of the substrate 11 opposite to a main surface 11a is polished. The thickness of the substrate 11 after being polished is, for example, 10 μm or more and 50 μm or less, preferably 15 μm or more and 40 μm or less, and more preferably 25 μm or more and 35 μm or less. The first light-transmissive member 24 is obtained by polishing the substrate 11

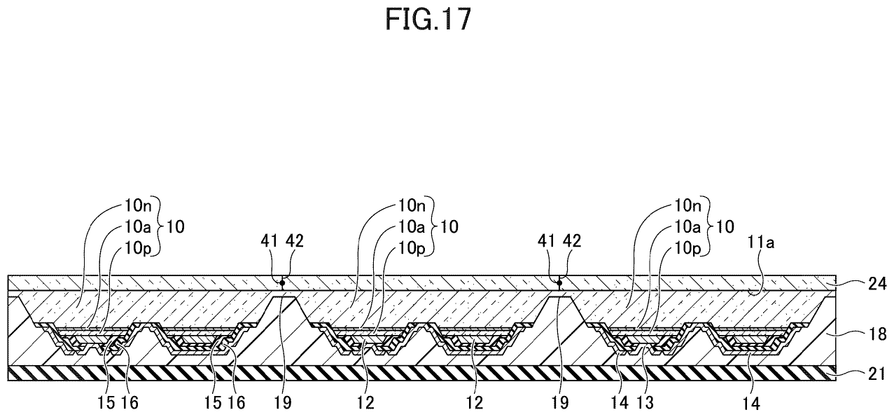

Subsequently, the inside of the first light-transmissive member 24 is irradiated with laser light. The laser light is focused at a specific depth position inside the first light-transmissive member 24, energy of the laser light is concentrated at the position, and a modified portion 41 is formed as illustrated in FIG. 17. The modified portion 41 formed by the irradiation of the laser light generates stress, and the stress causes a crack 42 inside the first light-transmissive member 24. The modified portion 41 and the crack 42 are formed along each singulation line 30 (see FIG. 14).

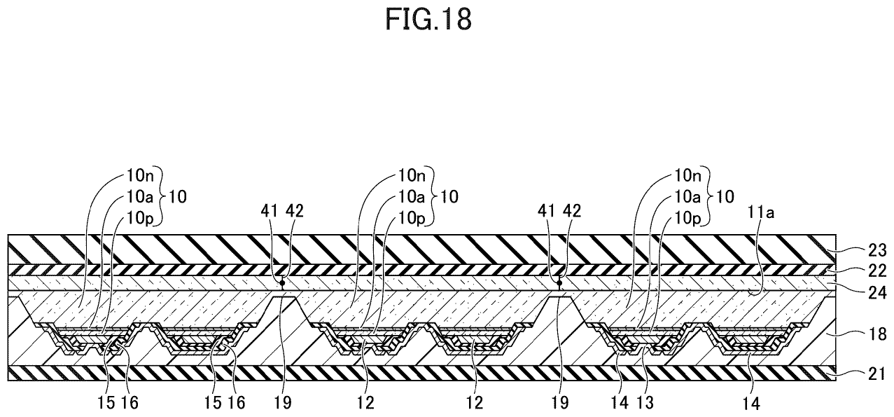

A layered body of the dielectric film 22 and the second light-transmissive member 23 is separately prepared, and the dielectric film 22 is bonded to the first light-transmissive member 24 as illustrated in FIG. 18. In the preparation of the layered body of the dielectric film 22 and the second light-transmissive member 23, for example, the dielectric film 22 is formed, by the sputtering method, on a surface of the second light-transmissive member 23 opposite to a surface serving as a third surface 23a, the dielectric film 22 is subjected to CMP, and the thickness of the second light-transmissive member 23 is adjusted by being polished.

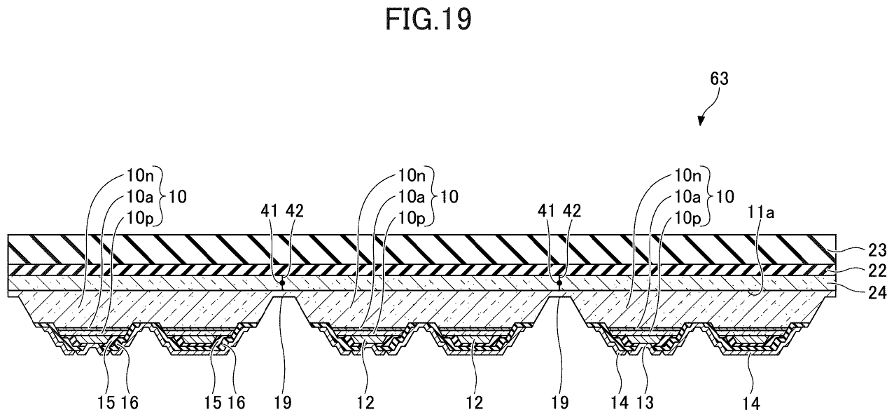

Subsequently, as illustrated in FIG. 19, the support substrate 21 and the resin member 18 are removed, and an intermediate member 63 in which a plurality of semiconductor parts 10 are bonded to one set of the first light-transmissive member 24, the dielectric film 22, and the second light-transmissive member 23 is formed.

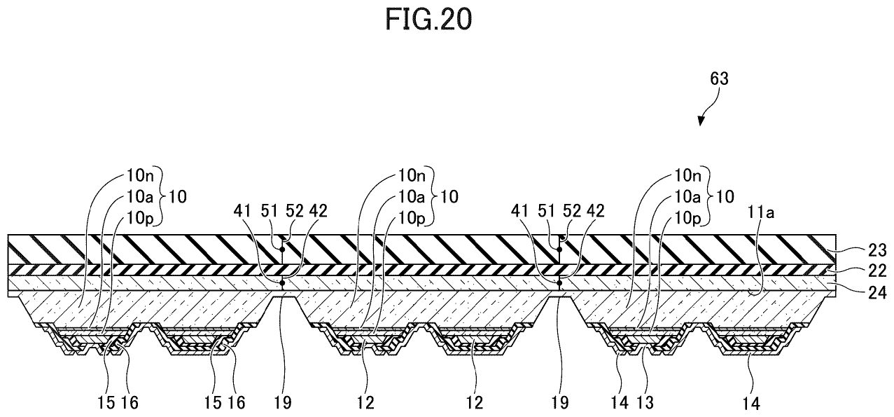

Subsequently, the inside of the second light-transmissive member 23 is irradiated with laser light. The laser light is focused at a specific depth position inside the second light-transmissive member 23, energy of the laser light is concentrated at this position, and a modified region 51 is formed as illustrated in FIG. 20. The modified portion 51 formed by the irradiation by the laser light generates stress, and the stress causes a crack 52 inside the second light-transmissive member 23. The modified portion 51 and the crack 52 are formed along each singulation line 30.

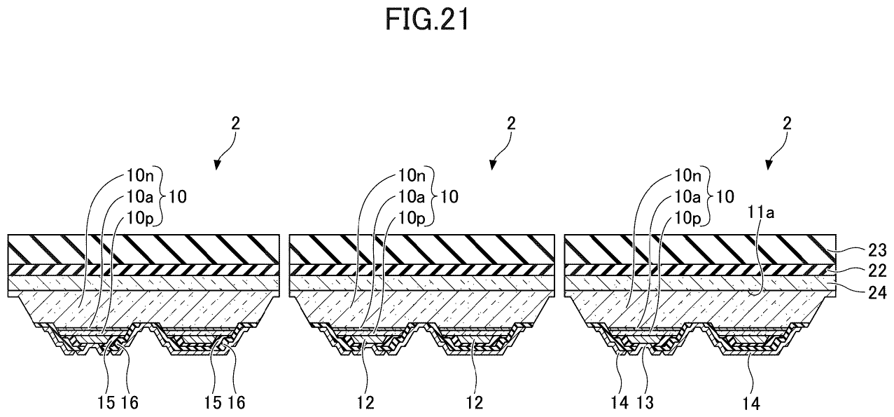

Subsequently, as illustrated in FIG. 21, the intermediate member 63 is cleaved and singulated into a plurality of light-emitting devices 2. Each of the plurality of light-emitting devices 2 includes a semiconductor part 10, a first light-transmissive member 24, a dielectric film 22, and a second light-transmissive member 23. A method of cleaving the intermediate member 63 is not limited.

In this manner, the plurality of light-emitting devices 2 can be manufactured.

In the second embodiment, the dielectric film 22 and the second light-transmissive member 23 may be disposed by the same method as in the first embodiment.

According to the present disclosure, both improvement of light extraction efficiency and improvement of the bonding strength between a dielectric film and a light-transmissive member can be achieved.

Although embodiments have been described in detail above, the above-described embodiments are non-limiting examples, and various modifications and substitutions can be made to the above-described embodiments without departing from the scope described in the claims.

What is claimed is:

1. A light-emitting device comprising:
a semiconductor part comprising a light-emitting layer;
a dielectric film disposed on an upper surface of the semiconductor part and comprising an oxide; and
a light-transmissive member disposed on an upper surface of the dielectric film, wherein
a refractive index of the dielectric film is lower than a refractive index of the semiconductor part and is closer to a refractive index of the light-transmissive member than to the refractive index of the semiconductor part,
the oxide contains Al and Ta, and
when a sum of an Al content in the oxide and a Ta content in the oxide is taken as 100 atomic %, the Ta content is greater than 0 atomic % and less than or equal to 60 atomic %.

2. The light-emitting device according to claim 1, wherein the Ta content is greater than 0 atomic % and less than 25 atomic %.

3. The light-emitting device according to claim 1, wherein the Ta content is 25 atomic % or more and 60 atomic % or less.

4. The light-emitting device according to claim 1, wherein an arithmetic average roughness Ra of the upper surface of the semiconductor part is 100 nm or more and 250 nm or less.

5. The light-emitting device according to claim 1, wherein the refractive index of the dielectric film is higher than the refractive index of the light-transmissive member.

6. The light-emitting device according to claim 1, wherein the content of Ta in the dielectric film is larger in a lower surface side of the dielectric film than in an upper surface side of the dielectric film.

7. The light-emitting device according to claim 1, wherein the light-transmissive member comprises a phosphor.

8. The light-emitting device according to claim 1, wherein the light-emitting layer is configured to emit light having a peak emission wavelength in a range of 350 nm or more and 500 nm or less.

9. The light-emitting device according to claim 1, wherein the refractive index of the light-transmissive member is 1.7 or more and 1.9 or less.

10. The light-emitting device according to claim 1, wherein the refractive index of the semiconductor part is 2.0 or more and 3.0 or less.

11. The light-emitting device according to claim 1, wherein a thickness of the dielectric film is 1 μm or more and 50 μm or less.

12. The light-emitting device according to claim 1, wherein a thickness of the light-transmissive member is 100 μm or more and 400 μm or less.

13. A light-emitting device comprising:
a semiconductor part comprising a light-emitting layer;
a first light-transmissive member disposed on an upper surface of the semiconductor part;
a dielectric film disposed on an upper surface of the first light-transmissive member and comprising an oxide; and
a second light-transmissive member disposed on an upper surface of the dielectric film, wherein
a refractive index of the dielectric film is lower than a refractive index of the semiconductor part and is closer to a refractive index of the second light-transmissive member than to the refractive index of the semiconductor part,
a refractive index of the first light-transmissive member is lower than the refractive index of the semiconductor part and is closer to the refractive index of the dielectric film than to the refractive index of the semiconductor part,
the oxide contains Al and Ta, and
when a sum of an Al content in the oxide and a Ta content in the oxide is taken as 100 atomic %, the Ta content is greater than 0 atomic % and less than or equal to 60 atomic %.

14. The light-emitting device according to claim 13, wherein the refractive index of the first light-transmissive member is lower than the refractive index of the dielectric film.

15. The light-emitting device according to claim 13, wherein the first light-transmissive member is a sapphire substrate.
